(19) United States
(12) Patent Application Publication
(10) Pub. No.: US 2007/0275543 A1
(43) Pub. Date: Nov. 29, 2007

(54) Manufacturing method of a semiconductor device

(75) Inventors: Yoshiyuki Abe, Tokoyo (JP); Hideo Muto, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/700,926

(22) Filed: Feb. 1, 2007

(30) Foreign Application Priority Data
Mar. 30, 2006 (JP) 2006-93300

(51) Int. Cl. H01L 21/78

(52) U.S. Cl. 438/464; 257/E21.599

(57) ABSTRACT

This invention aims at improvement in reliability of a semiconductor device. In this invention, a semiconductor wafer is irradiated with laser light so as to have a fractured layer formed in the interior of the semiconductor wafer, the semiconductor wafer is mounted on a dicing tape via paste (adhesive layer), then the paste of the dicing tape is hardened by UV irradiation or cooling, and subsequently the semiconductor wafer is bent (breaking). By this process, shifting and movement of semiconductor chips can be prevented because the paste has been hardened at the time of the bending. As a result, the semiconductor chip can be prevented from interfering with adjacent chips and can also be inhibited from generating chipping; therefore, the reliability of a semiconductor device can be improved.

### CROSS-REFERENCE TO RELATED APPLICATION

The present application claims priority from Japanese patent application No. 2006-93300 filed on Mar. 30, 2006, the content of which is hereby incorporated by reference into this application.

### BACKGROUND OF THE INVENTION

The present invention relates to a manufacturing technology of a semiconductor device and, more particularly, to a manufacturing method of a semiconductor device that uses a dicing tape.

There exists a technology that is specified to have a process of mounting a wafer with a protection sheet attached thereon and with a backside being ground to a very thin thickness on a first ring frame via a first adhesive sheet with its backside facing the outside and dicing the wafer in this state from the backside, and a process of turning the diced wafer upside down and attaching it again to a second ring frame via a second adhesive sheet (for example, see Japanese Unexamined Patent Publication No. 2005-228794 (FIG. 1)).

### SUMMARY OF THE INVENTION

In the dicing process of the manufacturing process of a semiconductor device, a semiconductor wafer is cut along a lattice-shaped region, called a scribe area, of a principal plane of a semiconductor wafer (hereinafter also referred to simply as a wafer) to form semiconductor chips (hereinafter also referred to simply as chips). In doing this, a cutting tool in the form of a disk called a dicing blade is used to cut the wafer. The wafer is divided into individual chips (dividing) with a dicing blade. After being separated individually, the chips are picked up by expanding spacings among chips in an expanding process. At this time, the pickup of the chip is performed after irradiating the dicing tape with UV following the expanding. Since this UV irradiation hardens a paste (adhesive layer or binder) of the dicing tape, thereby decreasing adhesive strength of the paste, the picking-up of the chips can be performed easily. That is, the paste of the dicing tape is in a soft state before performing the picking-up. This is because it is preferred that the paste is in a comparatively soft state at the time of using the dicing blade. The reason to do so is not to allow the chips being prepared as individual chips by dicing to disperse away from the dicing tape due to vibration of the dicing blade.

However, as the semiconductor wafer tends to be thin in recent years, a technology using a laser dicing method that replaces the blade dicing method has come to be known. The laser dicing method is also disclosed in the above-mentioned Japanese Unexamined Patent Publication No. 2005-228794. However, in the blade dicing method, a stress applied to the wafer is large as compared to the laser dicing method. Therefore, as a semiconductor wafer becomes thinner, there occurs a problem with the blade dicing method that chip clacking tends to be generated because of decrease in fracture strength of the semiconductor wafer.

In the laser dicing process, generally, after completion of backside grinding of the wafer, laser light is irradiated from the backside of the wafer to form a fractured layer (or called a modified layer or the like) in the interior of the wafer. After attaching the dicing tape on the wafer, a breaking work (bending work) is performed. In the breaking work, the wafer is bent, so that crack is generated from the fractured layer, which causes the wafer to divide into chips. Then, expanding for expanding spacings among chips is performed.

After the expanding, UV irradiation on the dicing tape is performed. Since this UV irradiation causes the paste (an adhesive layer or binder) of the dicing tape to be hardened and decreases the adhesive strength of the paste, the chips become easy to pick up.

However, this method comes with a problem that the chip may shift at the time of breaking of the wafer, and chipping may occur in a corner part on the backside of the chip. That is, when the wafer is bent at the time of the breaking, since the paste of the dicing tape is soft, a chip moves and interferes with adjacent chips, which generates chipping of a chip (chipping). This poses problems: reduction in reliability of the semiconductor device and decrease in the yield of the chips. When the dicing blade is used to divide the wafer into individual chips, the spacings among the adjacent chips that are divided is sufficiently secured because the dicing blade width is wider (thicker) than the width of a separated region made by laser dicing even if the paste of the dicing tape is soft; therefore, the adjacent chips do not interfere with one other in the picking-up of the chips.

Note that the breaking is a necessary work in order not to generate whisker defect in an inspection pattern on the wafer. That is, as shown in a whisker part 1V of an inspection pattern 1Wf of the comparative example in FIG. 25, if the expanding is performed without doing the breaking in advance, since the inspection pattern 1Wf formed on the principal plane of the wafer is formed with copper etc., which tends to last not so as to be cut, remaining as the whisker part 1V. Therefore, in order not to allow a whisker part 1V to form, it is necessary to perform the breaking in advance before the expanding.

If the paste is soft, a problem that the paste of the dicing tape adheres to a chip backside at the time of being expanded (the expanding) also arises. That is, when the dicing tape is expanded, the paste is also expanded and torn off. Especially, when the chip is mounted on the dicing tape via a DAF (Die Attach Film, adhesive film), if the paste of the dicing tape is soft, even if the DAF is be cut finely, the paste of the dicing tape adheres to the backside of the DAF. If the paste of the dicing tape has adhered to the backside of the DAF, the paste deteriorates by heat imposed on the DAF at the time of a temperature cycle test, reflow, etc., which causes a problem of degrading temperature-cycle-tolerance and reflow-tolerance.

Moreover, if the paste has adhered to the backside of DAF, when laminating the chip (or implementing it on a circuit board), there is a problem that flatness deteriorates, resulting in mounting defect.

The object of this invention is to provide a technology whereby improvement in reliability of a semiconductor device can be aimed at.

Moreover, another object of this invention is to provide a technology whereby improvement in the yield of obtaining semiconductor chips can be aimed at.

Further, another object of this invention is to provide a technology whereby fall of the temperature-cycle-tolerance and reflow-tolerance can be inhibited.

The above-mentioned and the other objects and new features of this invention will become clear from description and the accompanying drawings of this specification.

A summary of a representative example among inventions disclosed in the present application will be described briefly as follows.

To be concrete, this invention comprises the steps of: forming a fractured layer in the interior of a semiconductor wafer by irradiating laser light onto the semiconductor wafer; mounting the semiconductor wafer on a dicing tape via an adhesive layer; hardening the adhesive layer of the dicing tape; dividing the semiconductor wafer starting from the fractured layer by bending it; and expanding chip spacings by stretching the dicing tape from its peripheral part.

Effects obtained by the representative example among the inventions disclosed in this application will be described briefly as follows.

Since the adhesive layer (paste) of the dicing tape is hardened and subsequently the semiconductor wafer is bent, shifting and movement of the semiconductor chip can be prevented because the paste has hardened at the time of the bending. As a result, generation of chipping can also be inhibited and improvement in the reliability of a semiconductor device can be attained.

Since the paste has hardened at the time of being expanded (the expanding) by hardening the adhesive layer (paste) of the dicing tape and subsequently performing the expanding of the semiconductor wafer, the paste is not torn off and can be prevented from adhering to the backside of the DAF. As a result, the fall of the temperature-cycle-tolerance and the reflow-tolerance can be prevented.

### BRIEF DESCRIPTION OF THE DRAWINGS

FIG. 1 is a flow diagram showing one example of a manufacturing method of a semiconductor device of a first embodiment of this invention;

FIG. 2 is a sectional view showing one example of a BG-tape attached state in a flow shown in FIG. 1;

FIG. 3 is a conceptual diagram showing one example of a thickness measurement state of a wafer in the flow shown in FIG. 1;

FIG. 4 is a conceptual diagram showing one example of a thickness measuring instrument of the wafer in the flow shown in FIG. 1;

FIG. 5 is a conceptual diagram showing one example of an output waveform of the thickness measuring instrument shown in FIG. 4;

FIG. 6 is a plan view showing one example of a construction of a backside grinding (BG) machine in the flow shown in FIG. 1;

FIG. 7 is a conceptual diagram showing one example of a backside grinding state in the flow shown in FIG. 1;

FIG. 8 is a conceptual diagram showing one example of a laser dicing state in the flow shown in FIG. 1;

FIG. 9 is a sectional view showing one example of a structure after attaching a DAF in the flow shown in FIG. 1;

FIG. 10 is a sectional view showing one example of a wafer mount state in the flow shown in FIG. 1;

FIG. 11 is a sectional view showing one example of a breaking state in the flow shown in FIG. 1;

FIG. 12 is a sectional view showing one example of an expanding state in the flow shown in FIG. 1;

FIG. 13 is a perspective diagram showing one example of a construction of pickup equipment used at the time of the expanding shown in FIG. 12;

FIG. 14 is a plan view showing one example of a structure of an inspection pattern divided into portions by the expanding shown in FIG. 12;

FIG. 15 is a sectional view showing one example of a picking-up state in the manufacturing method of a semiconductor device of the first embodiment of this invention;

FIG. 16 is a perspective diagram showing one example of a die bonding method in the manufacturing method of a semiconductor device of the first embodiment of this invention;

FIG. 17 is a sectional view showing one example of a die bonding method of a second (upper) chip in the manufacturing method of a semiconductor device of the first embodiment of this invention;

FIG. 18 is a sectional view showing one example of a structure after wire bonding in the manufacturing method of a semiconductor device of the first embodiment of this invention;

FIG. 19 is a sectional view showing one example of a structure after resin sealing and bump formation in the manufacturing method of a semiconductor device of the first embodiment of this invention;

FIG. 20 is a flow diagram showing one example of the manufacturing method of a semiconductor device of a second embodiment of this invention;

FIG. 21 is a sectional view showing one example of a wafer mount state in the flow shown in FIG. 20;

FIG. 22 is a sectional view showing one example of a UV irradiation state in the flow shown in FIG. 20;

FIG. 23 is a sectional view showing one example of the expanding state in the flow shown in FIG. 20;

FIG. 24 is a sectional view showing one example of the picking-up state in the manufacturing method of a semiconductor device of the second embodiment of this invention; and

FIG. 25 is a plan view showing a structure of an inspection pattern of the comparative example.

### DETAILED DESCRIPTION OF THE PREFERRED EMBODIMENTS

In embodiments below, explanation of identical or the same parts will not be repeated in principle except in cases of necessity.

Moreover, in the embodiments below, if it is necessary for the sake of convenience, the embodiments are divided into a plurality of sections or embodiments, which will be explained. Except for cases specially specified, they are not irrelevant to one another but have relations: one of them is a modification, details, supplementary information, or the like of a part or the whole of the others.

Furthermore, it should be understood that, when in the following embodiments the number of constituents or the like (including respective numbers, numerals, amounts, ranges, etc.) is referred to, the number is not limited to that specific number but may be another number more than or less than the specific number.

Hereafter, the embodiments of this invention will be explained in detail with reference to the drawings. Note that in all the figures used to explain the embodiments, a member having the same function is given the same reference numeral, and repeated explanation thereof will be omitted.

### First Embodiment

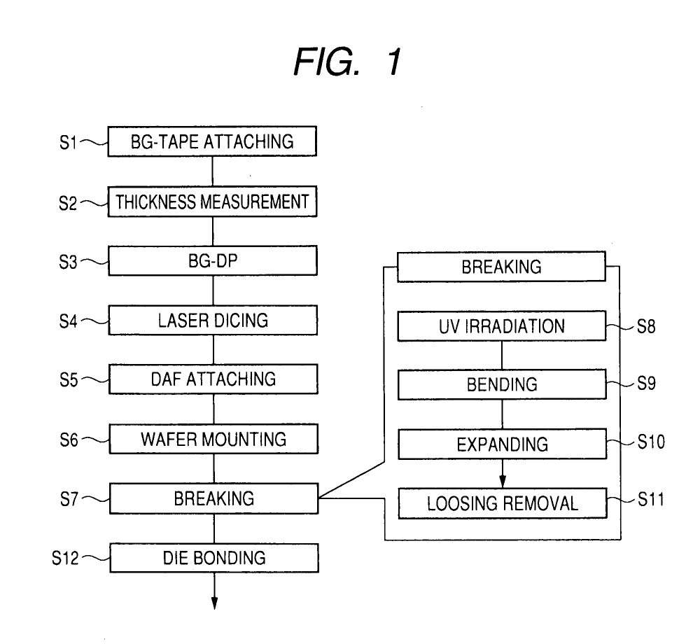

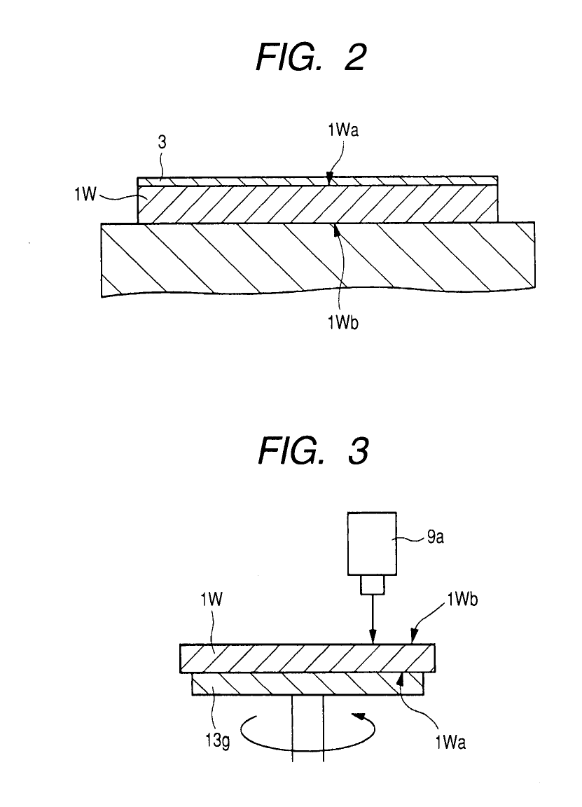

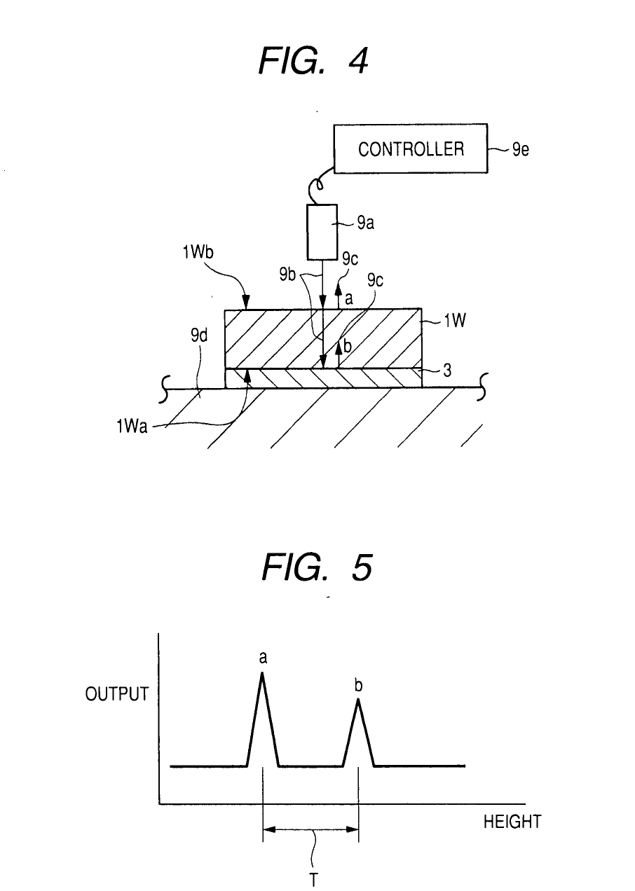

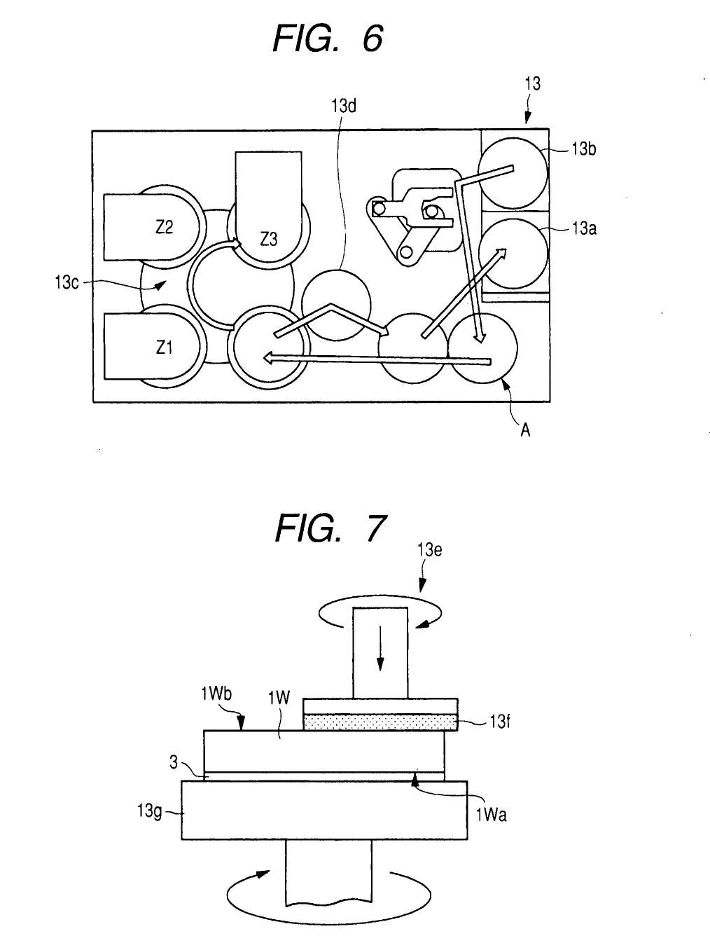

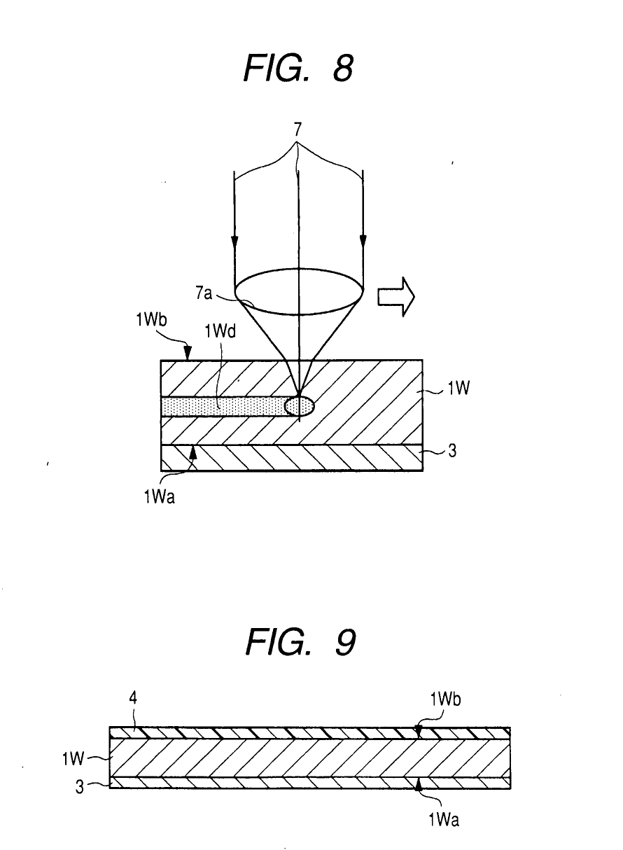

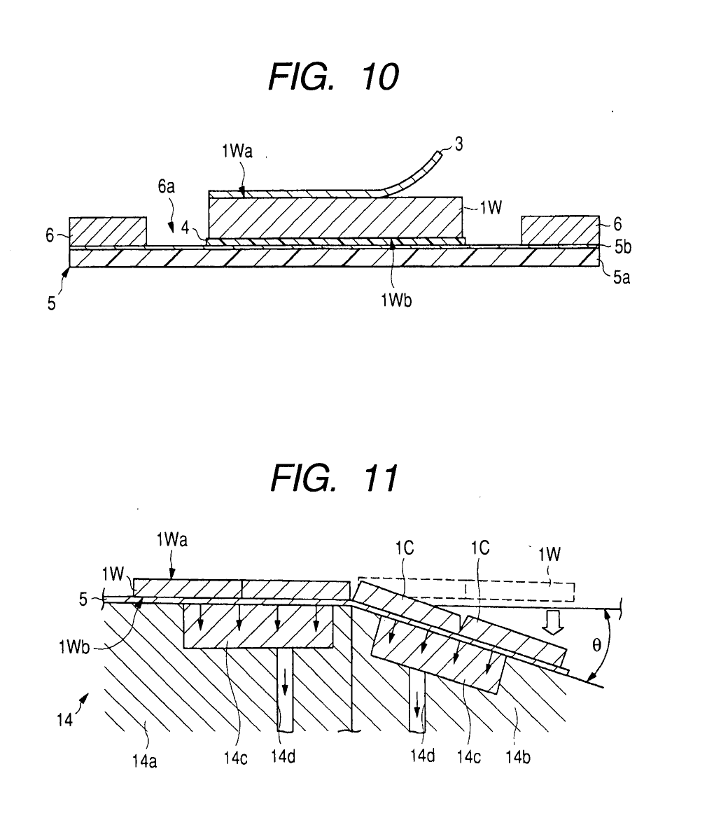

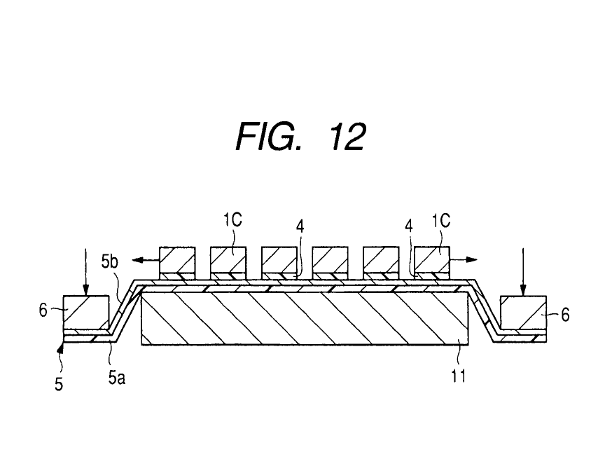

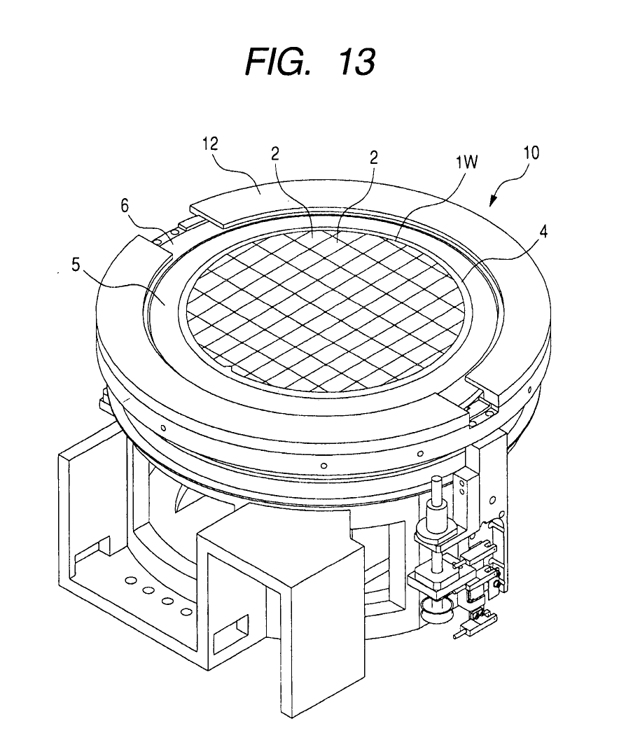

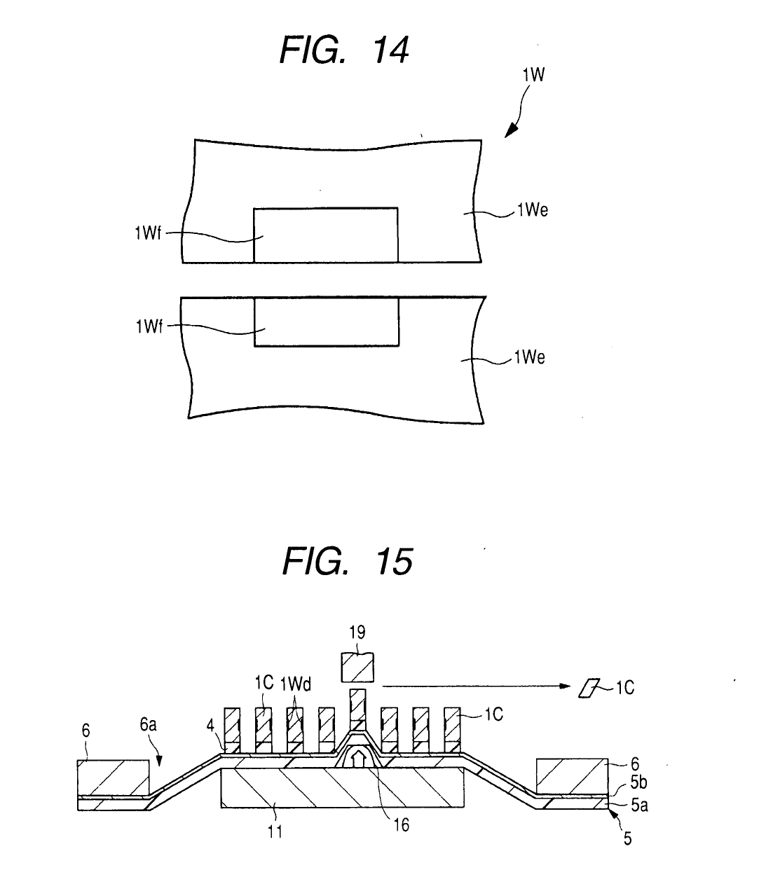

FIG. 1 is a flow diagram showing one example of a manufacturing method of a semiconductor device of a first embodiment of this invention; FIG. 2 is a sectional view showing one example of a BG-tape attached state in the flow shown in FIG. 1; FIG. 3 is a conceptual diagram showing one example of a state of thickness measurement of the wafer in the flow shown in FIG. 1; FIG. 4 is a conceptual diagram showing one example of a wafer thickness measuring instrument in the flow shown in FIG. 1; and FIG. 5 is a conceptual diagram showing one example of an output waveform of the thickness measuring instrument shown in FIG. 4. Moreover, FIG. 6 is a plan view showing one example of a construction of backside BG equipment in the flow shown in FIG. 1; FIG. 7 is a conceptual diagram showing one example of a backside grinding state in the flow shown in FIG. 1; FIG. 8 is a conceptual diagram showing one example of a laser dicing state in the flow shown in FIG. 1; FIG. 9 is a sectional diagram showing one example of a structure after DAF attachment in the flow shown in FIG. 1; and FIG. 10 is a sectional view showing one example of a wafer mount state in the flow shown in FIG. 1. Further, FIG. 11 is a sectional view showing one example of a breaking state in the flow shown in FIG. 1; FIG. 12 is a sectional view showing one example of an expanding state in the flow shown in FIG. 1; FIG. 13 is a perspective diagram showing one example of a construction of pickup equipment used at the time of the expanding shown in FIG. 12; and FIG. 14 is a plan view showing one example of a structure of the inspection pattern divided by the expanding shown in FIG. 12.

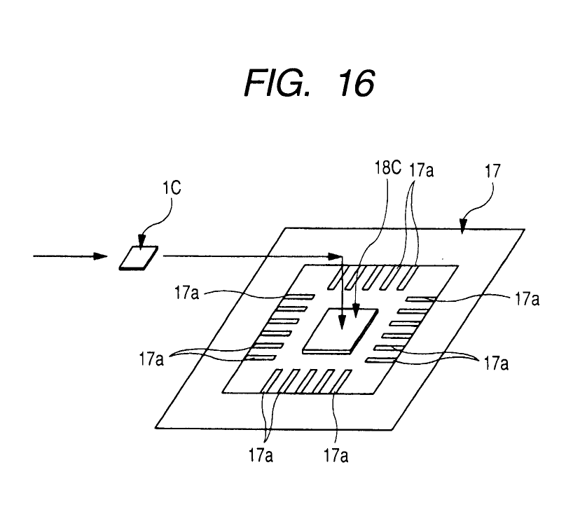

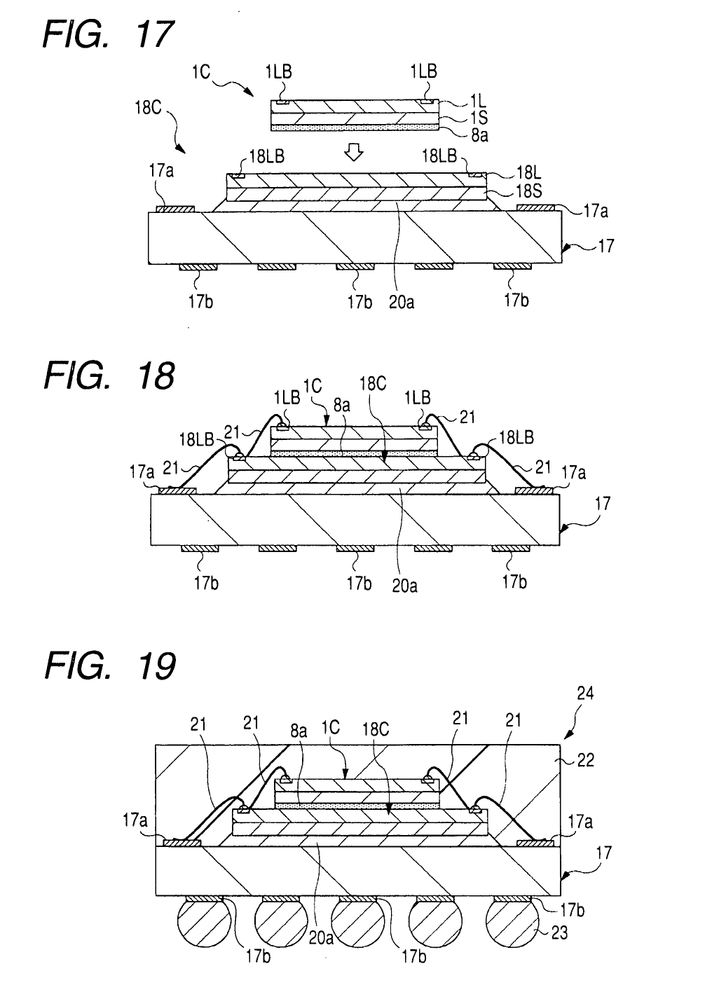

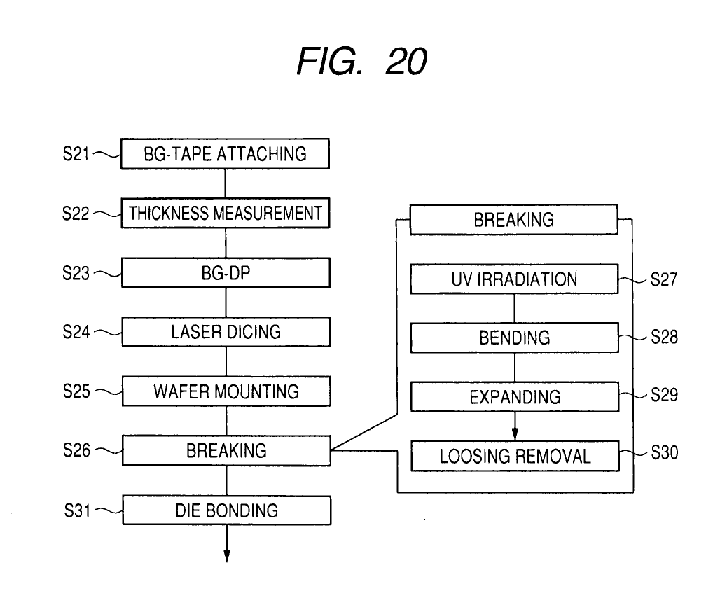

Still further, FIG. 15 is a sectional view showing one example of a picking-up state of the first embodiment of this invention; FIG. 16 is a perspective diagram showing one example of a die bonding method of the first embodiment of this invention; FIG. 17 is a sectional view showing one example of the die bonding method of a second (upper) chip of the first embodiment of this invention; FIG. 18 is a sectional view showing one example of a structure after wire bonding of the first embodiment of this invention; and FIG. 19 is a sectional view showing one example of a structure after resin sealing and bump formation of the first embodiment of this invention.

A manufacturing method of a semiconductor device of the first embodiment relates to assembly of a semiconductor device with a mounted thin semiconductor chip (for example, chip thickness is 50 μm or less).

The assembly of the semiconductor device of the first embodiment will be explained along the flow diagram shown in FIG. 1.

First, a semiconductor wafer 1W shown in FIG. 2 is prepared. The semiconductor wafer has a principal plane 1Wa on which a plurality of chip regions 2 shown in FIG. 13 are formed and a backside 1Wb facing this principal plane 1Wa. Further, as shown in FIG. 14, the inspection pattern 1Wf is formed in a scribe area 1We of the principal plane 1Wa of the semiconductor wafer 1W. The inspection pattern 1Wf is formed with a copper alloy, for example.

Then, BG (Backside Grinding) tape attaching shown in Step S1 of FIG. 1 is performed. In this process, as shown in FIG. 2, a BG tape (tape for grinding) 3 is attached to the principal plane 1Wa of the semiconductor wafer 1W.

Next, thickness measurement shown in Step S2 of FIG. 1 is performed as it is. In this measurement, as shown in FIG. 4, near infrared light 9b that is infrared radiation is irradiated on the semiconductor wafer 1W and reflected light 9c from interfaces (the backside 1Wb and the principal plane 1Wa) of the semiconductor wafer 1W is detected, whereby thickness of the semiconductor wafer 1W is measured. For example, the semiconductor wafer 1W fixed to a chuck table 9d via the BG tape 3 is irradiated with the near infrared light 9b from its backside 1Wb side (from the above) by the thickness measuring instrument 9a, such as an infrared camera connected with a controller 9e, reflected light 9c(a) from the backside 1Wb and reflected light 9c(b) for the principal plane 1Wa are detected, and a distance T between peaks of the reflected light 9c′(a) and the reflected light 9c(b) is derived, as shown in FIG. 5. In this case, the distance T between the peaks of the reflected light 9c(a) and the reflected light 9c(b) indicates the thickness of the semiconductor wafer 1W.

In the thickness measurement, the semiconductor 1W is placed on a rotary table 13g, as shown in FIG. 3, and the thickness is measured while rotating the rotary table 13g, whereby it becomes possible to perform thickness measurement at a plurality of locations on the plane of the semiconductor wafer 1W. The thickness of the semiconductor wafer 1W can be determined with a high accuracy by calculating a mean value of these measured values.

The wavelength of the near-infrared light 9b is 800 to 3000 nm.

Since by the method of measuring the semiconductor wafer 1W of this first embodiment, the thickness of the semiconductor wafer 1W is measured by calculating a distance T between the peaks of the reflected light 9c from the backside 1Wb and that from the principal plane 1Wa, a thickness of the wafer itself not involving the thickness of the BG tape 3 can be measured.

Therefore, the thickness of the semiconductor wafer 1W can be measured with a high accuracy. Moreover, since the thickness of the semiconductor wafer 1W can be measured with a high accuracy in grinding (BG) of the backside 1Wb of the semiconductor wafer 1W, the amount of grinding can be calculated with a high accuracy, and accordingly finally the thickness of the semiconductor wafer 1W can be finished with a high accuracy.

Furthermore, since in this thickness measurement method the backside can be ground while the amount of grinding is being corrected, the wafer can be ground without causing thickness defect. That is, by providing the rotary table 13g shown in FIG. 3 and the thickness measuring instrument 9a in the BG equipment shown in FIG. 6, the grinding of the backside 1Wb can also be done while the thickness of the semiconductor wafer 1W is being measured in the backside grinding process.

Here, FIG. 6 shows one example of a construction of BG equipment 13, which has a loader 13a, an unloader 13b, a grinding section 13c (Z1 to Z3), and a BG tape cleaning section 13d. When performing the backside grinding in the BG equipment 13 of FIG. 6, the backside grinding can be performed with a high accuracy while correcting the amount of grinding, for example, by disposing the thickness measuring instrument 9a and the rotary table 13g in the A part.

However, the thickness measurement of the semiconductor wafer 1W needs not to be done in the backside grinding process, and may be performed as a thickness measurement process prior to the backside grinding process.

Next, BG-DP (dry polishing) shown in Step S3 of FIG. 1 is performed. To be concrete, the backside 1Wb of the semiconductor wafer 1W is ground, based on a measurement result of the thickness of the semiconductor wafer 1W. Alternatively, while the thickness is being measured, the backside 1Wb of the semiconductor wafer 1W is ground until the thickness of the semiconductor wafer 1W reaches a desired thickness. Grinding is performed by the grinding section 13c of the BG equipment 13 shown in FIG. 6. In the grinding section 13c, as shown in FIG. 7, the semiconductor wafer 1W is fixed onto the rotary table 13g via the BG tape 3, and the backside 1Wb of the semiconductor wafer 1W is ground with a grinding stone 13f of a grinder 13e in this state so that the thickness of the semiconductor wafer 1W may be adjusted to the desired thickness.

Then, the scribe area 1We of the semiconductor wafer 1W (see FIG. 14) is irradiated with the near infrared light (infrared radiation) 9b to allow calculation of positions onto which laser light 7 for laser dicing is to be irradiated. In this process, a thickness measurement method shown in FIG. 4 is adopted and the laser irradiation positions are derived by irradiating the near infrared light 9b on the semiconductor wafer 1W.

After that, laser dicing shown in Step S4 of FIG. 1 is performed. In this process, as shown in FIG. 8, the laser light 7 is irradiated onto the scribe area 1We of the semiconductor wafer 1W to form a fractured layer (also called modified layer or the like) 1Wd in the interior of the semiconductor wafer 1W. To be concrete, the laser light 7 is irradiated onto the irradiation positions in the scribe area 1We of the semiconductor wafer 1W, derived by irradiation of the near infrared light 9b via a converging lens 7a, thereby forming the fractured layer 1Wd in its interior. In doing so, the laser light 7 is moved at a speed of 600 mm/sec, for example. Incidentally, the wavelength of the laser light 7 for laser dicing is 1064 nm.

Then, DAF attaching shown in Step S5 is performed. First, as shown in FIG. 9, a DAF 4 that is an adhesive film is attached on the backside 1Wb of the semiconductor wafer 1W. The DAF 4 is formed in the shape of a film and made of a die bond material. Following this, as shown in wafer mounting in Step S6 of FIG. 1 and in FIG. 10, the semiconductor wafer 1W is mounted on a dicing tape 5 via the DAF 4, and the BG tape 3 is peeled after the mounting. To be concrete, the semiconductor wafer 1W is mounted on the dicing tape 5 so that the DAF 4 of the backside 1Wb of the semiconductor wafer 1W and a paste (adhesive layer) 5b of the dicing tape 5 may contact each other, and subsequently the BG tape 3 is peeled.

Incidentally, the dicing tape 5 consists of a base material 5a formed from a resin, such as polyolefin (PO), and the paste (adhesive layer) 5b formed on the base material 5a. In this case, the paste 5b is of an ultraviolet curing type. A ring jig 6 is attached to a peripheral part of the dicing tape 5. The semiconductor wafer 1W is mounted on its opening 6a.

Then, the dicing tape 5 is irradiated with ultraviolet radiation. By this, the paste 5b of the dicing tape 5 is hardened.

After that, the breaking shown in Step S7 is performed. To be concrete, the semiconductor wafer 1W is bent and divided at the fractured layer 1Wd. In this process, first, the ultraviolet radiation (UV) shown in Step S8 is irradiated on the paste (adhesive layer) 5b of the dicing tape 5. Then, the bending shown in Step S9 is performed. FIG. 11 shows a principal part of breaking equipment 14 for bending a wafer; a semiconductor wafer 1W is placed so as to cover bar regions 14c of a first table 14a and a second table 14b, the tables suck the semiconductor wafer 1W tightly by vacuum from their suction holes 14d, and in this state the wafer is cut at the fractured layer 1Wd by application of stress to the fractured layer 1Wd of the semiconductor wafer 1W, for example, by tilting only the second table 14b by a predetermined angle θ. For example, θ is 2°.

In doing this, in the case where the paste 5b has been hardened in advance by irradiating the ultraviolet radiation on the dicing tape 5, shifting and movement of the chips at the time of bending the wafer can be prevented. This can also prevent the chip from interfering with adjacent chips and inhibit generation of chipping.

However, in the case where there exists the DAF 4 like this first embodiment, even if the paste 5b has not been hardened prior to the breaking process, a semiconductor wafer chip 1C is held on the dicing tape 5 thanks to the adhesive power of the DAF 4; therefore, shifting of the chip and the like are hard to occur. Therefore, the hardening is not necessarily performed prior to the breaking process (bending process in Step S9) in Step S7. However, as in this embodiment, by irradiating ultraviolet radiation on the dicing tape 5 after the mounting of the semiconductor wafer 1W on the dicing tape 5, the chip 1C can be held surely also in the breaking process. By this mechanism, even in the case where the DAF 4 is attached to the backside 1Wb of the semiconductor wafer 1W, the above effect is still available.

After completion of the bending, the expanding shown in Step S10 is performed. First, the DAF 4 that is an adhesive film is hardened. Then, the expanding is performed in the state where DAF 4 is hardened. To be concrete, in a state where the DAF 4 is hardened, the dicing tape 5 is stretched from its peripheral part, so that chip spacings are expanded.

In the expanding, as shown in FIGS. 12 and 13, first, the dicing tape 5 that is attached to the semiconductor wafer 1W is positioned horizontally on a support ring 11 of pickup equipment 10, and the ring jig 6 joined to the peripheral part of the dicing tape 5 is held by the expanding ring 12. As shown in FIG. 15, in the inside of the support ring 11, a push-up horse 16 for pushing the semiconductor chip 1C upward is disposed.

Next, by lowering an expand ring 12 of the pickup equipment 10, the ring jig 6 joined to the peripheral part of the dicing tape 5 is pushed downward, as shown in FIG. 12. When the ring jig 6 has been pushed downward, the dicing tape 5 is received strong tension that directs toward the periphery (peripheral part) from its center and stretched in horizontal directions, thereby removing loosing. Since this tension causes the chip regions shown in FIG. 13 to separate from one another along the fractured layer 1Wd formed in the scribe area 1We of the semiconductor wafer 1W, as a result, the plurality of semiconductor chips 1C that are divided individually are obtained, as shown in FIG. 12.

Since at this time, the DAF 4 on the backside 1Wb of the semiconductor wafer 1W is also stretched along with the dicing tape 5 and the chips are separated as individual chips, the DAF 4 of the same size as the semiconductor chip 1C remains on the backside of each of the semiconductor chips 1C that are divided individual chips.

In this first embodiment, since the expanding is performed with the DAF 4 hardened, the DAF 4 can be divided surely at the time of the expanding. As a result, at the time of the picking-up, the semiconductor chip 1C can be picked up surely, and generation of chipping etc. can be inhibited. By this, improvement in the reliability of a semiconductor device (CSP 24 shown in FIG. 19) can be attained. Moreover, the yield of obtaining the semiconductor chips 1C can be raised.

Moreover, in the case where the paste 5b of the dicing tape 5 is hardened by UV irradiation prior to the bending, the paste 5 can be prevented from adhering to the backside of the DAF 4 while the paste 5b is not torn off because the paste has been hardened at the time of the expanding. Accordingly, the paste 5b has not adhered to the backside of the DAF 4; therefore, the fall of the temperature-cycle-tolerance and the reflow-tolerance in the subsequent process can be inhibited. In addition, since the paste 5b has not adhered to the backside of the DAF 4, the chip is inhibited from degrading in flatness and subsequently leading to mounting defect in laminating the semiconductor chips 1C (or mounting them in the circuit board) in the chip mounting process that will be described or the like.

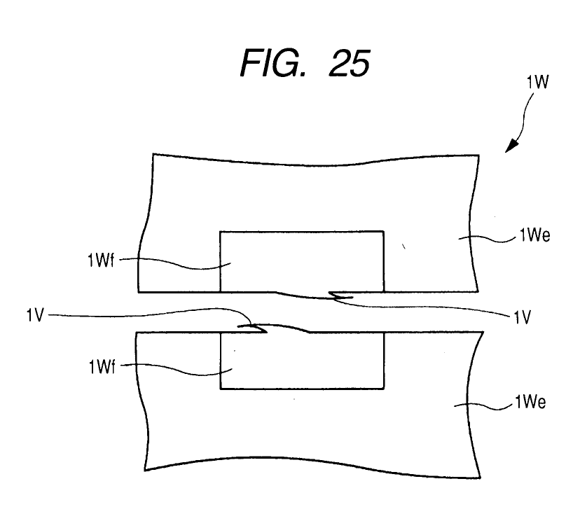

Moreover, by performing the bending (breaking) prior to the expanding, the inspection pattern 1Wf can be cut without forming the whisker part 1V (see FIG. 25), as shown in FIG. 14.

Note that if the wafer 1 is subjected to the UV irradiation prior to the expanding process, the problem that the paste 5b of the dicing tape 5 adheres to the backside to the DAF 4 can be prevented. If the UV irradiation process is placed after the breaking process, it becomes hard for the dicing tape 5 to be stretched so as to eliminate the loosing in the expanding process. Doing the process in this way comes from a fact that if the breaking process is performed in a state where the adhesive layer 5b of the dicing 5 is not hardened, only the semiconductor wafer 1W is divided. Therefore, if the UV irradiation is performed after the breaking process, the dicing tape 5 is hardened in a state where crack is not formed in the dicing tape 5. Because of this, the hardened dicing tape 5 becomes hard to stretch in the expanding process. Contrary to this, like this first embodiment, if the UV irradiation is performed prior to the breaking process, both the semiconductor wafer 1We and at least a part of the hardened dicing tape 5 are divided in the breaking process. As a result, even if the dicing tape 5 is in a hardened state in the subsequent expanding process, the dicing tape 5 can easily be stretched because such a region of the dicing tape 5 that is overlapped two-dimensionally with the fractured layer 1Wd formed in the semiconductor wafer 1W has been divided.

Next, loosing removal shown in Step S11 of FIG. 1 is performed. This process removes the loosing of the dicing tape 5 generated by the expanding of the periphery that is the outer portion of a plurality of semiconductor chips 1C. After that, die bonding shown in Step S12 is performed. First, the chip picking-up shown in FIG. 15 is performed. To be concrete, the semiconductor chips 1C that are divided individual chips are picked up from the dicing tape 5. In this process, first, the push-up horse 16 is disposed under one semiconductor chip 1C, and a collet 19 capable of sucking and holding a chip for the picking up is disposed above the semiconductor chip 1C and is made contact with it closely.

Then, while pushing the semiconductor chip 1C upward with the help of the push-up horse 16, the collet 19 is moved upward to effect peeling of the semiconductor chip 1C and the DAF4 from the dicing tape 5.

In this way, the semiconductor chip 1C that is peeled from the dicing tape 5 and picked up is conveyed to the next process (pellet attaching process) by being sucked and held by the collet 19, and mounted on a circuit board 17, as shown in FIG. 16.

Next, the picked-up semiconductor chip 1C is transported onto the principal plane of a semiconductor chip 18C mounted on the principal plane of the circuit board 17, as shown in FIGS. 16 and 17. Incidentally, the semiconductor chip 18C is mounted on the principal plane of the circuit board 17, as the first (lower) chip, via the adhesive layer 20a.

Then, the semiconductor chip 1C is lowered while the adhesive layer 8a of the backside of the semiconductor chip 1C and the principal plane of the semiconductor chip 18C are made to face each other. Here, the adhesive layer 8a is the DAF 4 in this first embodiment. To be concrete, the semiconductor chip 1C is stacked (laminated) on the semiconductor chip 18C via the adhesive layer 8a (DAF 4). Incidentally, the number of laminated chips is not restricted to two, and any number of lamination may be adopted.

Here, one example of structures of the circuit board 17 and the semiconductor wafer 18C and a mounting method thereof will be explained. The circuit board 17 is made up of a printed circuit board having a multilayer wiring configuration, for example, and has a principal plane and a backside that are placed in mutually opposite sides across the thickness direction. The semiconductor chip 18C is mounted on the principal plane of the circuit board 17. Moreover, a plurality of electrodes 17a are arranged on the principal plane of the circuit board 17 so as to surround outer boundary of the semiconductor chip 18C. Moreover, a plurality of electrodes 17b are arranged on the backside of the circuit board 17. The electrode 17a on the principal plane of the circuit board 17 and the electrode 17b of the backside are electrically connected together through wiring in an inner layer of the circuit board 17. The wiring of the electrodes 17a, 17b of the circuit board 17 is made of copper, for example. Exposed surfaces of the electrodes 17a, 17b are given gold (Au) plating with a nickel (Ni) base.

Next, a structure of the semiconductor chip 18C will be explained. A semiconductor substrate 18S for the semiconductor chip 18C is made of silicon (Si) single crystal, for example, just like the semiconductor substrate 1S for a semiconductor chip 1C. On its principal plane, an element and a wiring layer 18L are formed. A structure of the wiring layer 18L is the same as the wiring layer 1L of the semiconductor chip 1C, and a pad 18LB is disposed on its top layer. The semiconductor chip 18C is mounted on the principal plane of the circuit board 17 with a principal plane of the semiconductor chip 18C facing the above and its backside being fixed to the principal plane of the circuit board 17 by the adhesive layer 20a. The adhesive layer 20a is formed with a thermoplastic resin like a polyimide resin, for example.

The DAF 4 may be used as a material of the adhesive layer 20a. That is, both the first semiconductor chip 18C and a second semiconductor chip 1C may be mounted via the DAF 4.

Next, as shown in FIG. 18, the pad 1LB of the second semiconductor chip 1C and the pad 18LB of the first semiconductor chip 18C are connected together using conductive wire 21; the pad 18LB of the first semiconductor chip 18C and the electrode 17a of the circuit board 17 are connected together using the wire 21. The pad 1LB of the second semiconductor chip 1c and the electrode 17a of the circuit board 17 may be connected together using the wire 21. The wire 21 is formed with gold (Au), for example.

Then, as shown in FIG. 19, the semiconductor chips 1C, 18C and more than one piece of wire 21 etc. are sealed with a resin. For example, a sealing member 22 is formed from an epoxy type resin or the like using the transfer mold method, and sealing is done with this sealing member 22. Moreover, a solder ball 23 is formed on the electrode 17b as an external terminal. The solder ball 23 is made up of a lead solder material of, for example, a lead (Pb)-tin (Sn) system or a lead-free solder material of, for example, a tin (Sn)-silver (Ag)-copper (Cu) system. In the above manner, the CSP 24 (semiconductor device) is manufactured.

### Second Embodiment

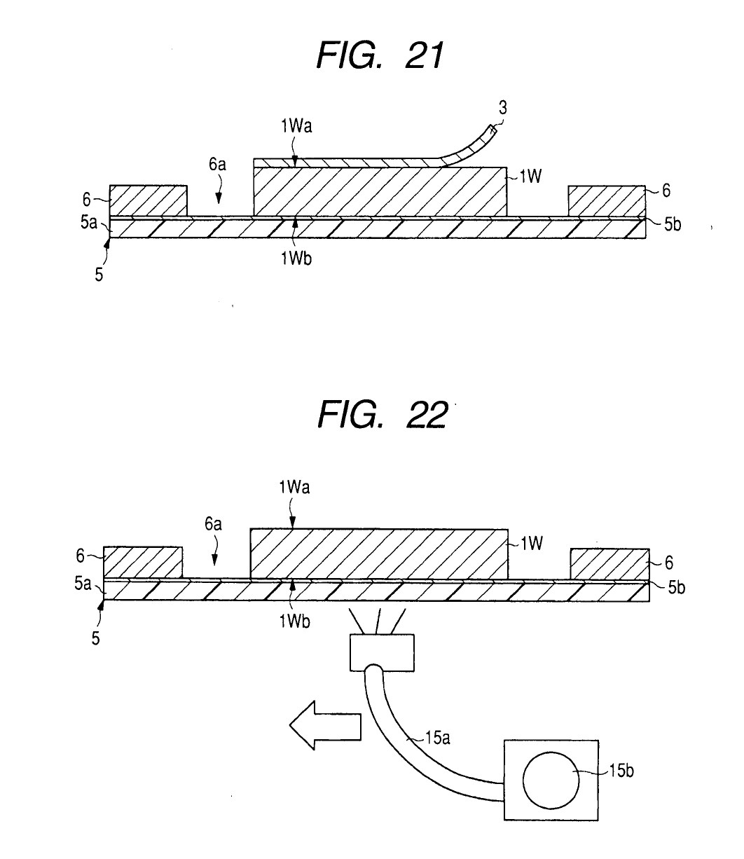

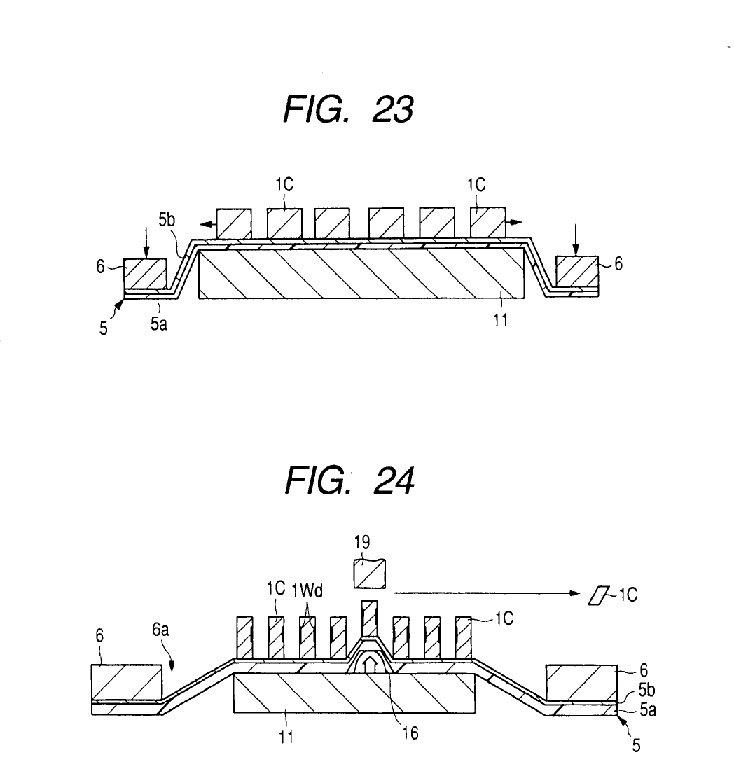

FIG. 20 is a flow diagram showing one example of a manufacturing method of a semiconductor device of a second embodiment of this invention. FIG. 21 is a sectional view showing one example of a wafer mount state in the flow shown in FIG. 20. FIG. 22 is a sectional view showing one example of a UV irradiation state in the flow shown in FIG. 20; FIG. 23 is a sectional view showing one example of an expanding state in the flow shown in FIG. 20, and FIG. 24 is a sectional view showing one example of a picking-up state in the manufacturing method of a semiconductor device of the second embodiment of this invention.

The manufacturing method of a semiconductor device of this second embodiment, like the first embodiment, relates to assembly of a semiconductor device with a mounted thin semiconductor chip of a chip thickness of 50 μm or less. A point different from the first embodiment is that, in mounting the wafer on the dicing tape 5, the semiconductor wafer 1W is directly mounted on the dicing tape 5 without using the DAF 4.

Assembly of the semiconductor device of this second embodiment will be explained along a flow diagram shown in FIG. 20.

First, the semiconductor wafer 1W is prepared, like the first embodiment. The semiconductor wafer 1W has the principal plane 1Wa on which a plurality of chip regions 2 shown in FIG. 13 are formed and the backside 1Wb facing this principal plane 1Wa. As shown in FIG. 14, the inspection pattern 1Wf is formed in the scribe area 1We of the principal plane 1Wa of the semiconductor wafer 1W. The inspection pattern 1Wf is formed with a copper alloy, for example.

Then, BG-tape attaching shown in Step S21 of FIG. 20 is performed. In this process, the BG tape 3 is attached on the principal plane 1Wa of the semiconductor wafer 1W.

Next, thickness measurement shown in Step S22 is performed as it is. In this process, thickness measurement is performed by the same method as the first embodiment. To be concrete, as shown in FIG. 4, the semiconductor wafer 1W is irradiated with the near infrared light 9b that is infrared radiation, and the reflected light 9c from the backside 1Wb and that from the principal plane 1Wa of semiconductor wafer 1W are detected, thereby allowing a thickness of the semiconductor wafer 1W to be measured.

Next, BG-DP (dry polishing) shown in Step S23 is performed. To be concrete, the backside 1Wb of the semiconductor wafer 1W is ground based on the measurement result of the thickness of the semiconductor wafer 1W. Alternatively, the backside 1Wb of the semiconductor wafer 1W is ground until the thickness of the semiconductor wafer 1W reaches a desired thickness, while measuring the thickness of the semiconductor wafer 1W.

Then, the near infrared light 9b is irradiated on the scribe area 1We of the semiconductor wafer 1W (see FIG. 14) to allow calculation of positions onto which the laser light 7 for laser dicing is to be irradiated. In this process, a thickness measuring method shown in FIG. 4 is adopted, and the laser irradiation positions are derived by irradiating the near infrared light 9b.

After that, the laser dicing shown in Step S24 is performed. Like the first embodiment, as shown in FIG. 8, the fractured layer (also called modified layer or the like) 1Wd is formed in the interior of the semiconductor wafer 1W by irradiating the scribe area 1We of the semiconductor wafer 1W with the laser light 7. To be concrete, the laser light 7 is irradiated onto the laser irradiation positions in the scribe area 1We of the semiconductor wafer 1W that are derived by irradiating the near infrared light 9b from the backside 1Wb side of the semiconductor wafer 1W, and the fractured layer 1Wd is formed in its interior. In this case, the wavelength of the laser light 7 for laser dicing is 1064 nm.

Then, the wafer mounting shown in Step S25 is performed. First, as shown in FIG. 21, the semiconductor wafer 1W is mounted on the dicing tape 5, and the BG tape 3 is peeled after the mounting. To be concrete, the semiconductor wafer 1W is mounted on the dicing tape 5 so that the backside 1Wb of the semiconductor wafer 1W and the paste (adhesive layer) 5b of the dicing tape 5 may contact each other, and subsequently the BG tape 3 is peeled.

The dicing tape 5 consists of the base material 5a formed from a resin, such as polyolefin (PO) and the paste (adhesive layer) 5b formed on the base material 5a. In this process, the paste 5b is of an ultraviolet curing type. Moreover, the ring jig 6 with an opening 6a is fixed to the peripheral part of the dicing tape 5. The semiconductor wafer 1W is mounted in the opening 6a.

Then, the breaking shown in Step S26 is performed. In the breaking, first, the UV irradiation shown in Step S27 is performed. In this process, as shown in FIG. 22, the dicing tape 5 is irradiated with ultraviolet radiation to effect hardening of the paste 5b of the dicing tape 5. In doing this, ultraviolet radiation is irradiated from the backside 1Wb side of the semiconductor wafer 1W. To be concrete, a fiber scope 15a connected with a UV lamp 15b is disposed on the backside 1Wb side of the semiconductor wafer 1W, the ultraviolet radiation is irradiated from the backside 1Wb side of the semiconductor wafer 1W. That is, since the dicing tape 5 is attached on the backside 1Wb of the semiconductor wafer 1W, irradiation of the ultraviolet radiation on the semiconductor wafer 1W from the backside 1Wb side thereof hardens the paste 5b of the dicing tape 5 surely.

Although in the UV irradiation shown in FIG. 22, a case where the UV lamp 15b including the fiberscope 15a is moved beneath the semiconductor wafer 1W is shown. However, a method in which the UV lamp 15b is fixed and the semiconductor wafer 1W is moved may be adopted, or alternatively a method in which both the UV lamp 15b and the semiconductor wafer 1W are fixed and the ultraviolet radiation is irradiated may be used. To be concrete, the following may be adopted: the UV lamp 15b is covered with a large reflector on the backside 1Wb side of the semiconductor wafer 1W, and the ultraviolet radiation is subjected to irregular reflection by the reflector, whereby the whole backside 1Wb of the semiconductor wafer 1W is irradiated with the ultraviolet radiation.

Next, the bending (the breaking) shown in Step S28 of FIG. 20 is performed. To be concrete, the semiconductor wafer 1W is bent by the same method as the first embodiment shown in FIG. 11, and allowed to be divided at the fractured layer 1Wd. At this breaking, since the paste 5b of the dicing tape 5 is hardened by the UV irradiation in this second embodiment, shifting and movement of the semiconductor 1C can be prevented at the time of the bending. This technique can prevent the semiconductor chip 1C from interfering with adjacent chips, thereby inhibiting generation of chipping. In this second embodiment, since the DAF 4 is not attached on the backside 1Wb of the semiconductor wafer 1W, the paste 5b of the dicing tape 5 needs to be hardened in advance prior to the breaking process.

As a result, improvement in the reliability of the semiconductor device (CSP 24) can be attained. In addition, the yield of obtaining the semiconductor chips 1C can be increased.

After the bending, the expanding shown in Step S29 is performed. To be concrete, chip spacings are expanded by stretching the dicing tape 5 from its peripheral part. In the expanding, as shown in FIGS. 13 and 23, first, the dicing tape 5 to which the semiconductor wafer 1W is joined is positioned horizontally on the support ring 11 of the pickup equipment 10, and the ring jig 6 joined to the peripheral part of the dicing tape 5 is held by the expand ring 12. As shown in FIG. 24, the push-up horse 16 for pushing the semiconductor chip 1C upward is disposed in the inside of the support ring 11.

Next, by lowering the expand ring 12 of the pickup equipment 10, the ring jig 6 joined to the peripheral part of the dicing tape 5 is pushed downward, as shown in FIG. 23. When the ring jig 6 is pushed downward, the dicing tape 5 is stretched in horizontal directions so as to remove the loosing by being received strong tension toward to the periphery (peripheral part) from its center. Since this tension makes the chip regions shown in FIG. 13 separate from one another along the fractured layer 1Wd formed in the scribe area 1We of the semiconductor wafer 1W, a plurality of semiconductor chips 1C that are divided individual chips can be obtained, as shown in FIG. 23.

In this second embodiment, since the paste 5b of the dicing tape 5 is hardened by UV irradiation prior to the expanding and the expanding is performed with the paste being hardened, the paste is not torn off at the time of the expanding and accordingly the paste 5b can be prevented from adhering to the backside of the chip. Therefore, since the paste 5b is not adhered on the backside of the chip, the chip can be inhibited from causing mounting defect because of degraded flatness of the chip when laminating the semiconductor chips 1C (or mounting on a circuit board) in a chip mounting process that will be described latter and the like.

Moreover, by performing the bending (breaking) prior to the expanding, like the first embodiment, the inspection pattern 1Wf can be cut off without forming the whisker part 1V (see FIG. 25), as shown in FIG. 14. Next, the loosing removal shown in Step S30 of FIG. 20 is performed. In this process, the loosing of the dicing tape 5 generated by the expanding at the peripheral part of a plurality of semiconductor chips 1C is removed.

Then, the die bonding shown in Step S31 is performed. First, the picking-up of a chip shown in FIG. 24 is performed. To be concrete, the semiconductor chips 1C that are divided individual chips are picked up from the dicing tape 5. In this process, first, the push-up horse 16 is disposed under one semiconductor chip 1C, the collet 19 for the picking-up capable of sucking and holding a semiconductor chip is disposed on the semiconductor chip 1C, and the both are made to contact together closely.

Then, the semiconductor wafer 1C is pushed upward by the push-up horse 16, and the collet 19 is moved upward, so that the semiconductor chip 1C is peeled from the dicing tape 5.

The semiconductor chip 1C that was peeled and picked up from the dicing tape 5 in this way is conveyed to the next process (pellet attaching process) by being sucked and held by the collet 19, and mounted on the circuit board 17 as shown in FIG. 16.

Since a method of laminating the semiconductor chip that is picked up (or mounting it on the circuit board) is the same as the explanations of FIGS. 16 to 19 in the first embodiment, the explanation will be omitted.

Since other effects obtained by the manufacturing method of a semiconductor device of this second embodiment are the same as the effects of the first embodiment, their repeated explanations will be omitted.

In the foregoing, the invention made by the present inventors was explained concretely based on the embodiments of this invention. However, it is natural that this invention is not restricted to the embodiments of the invention, and may be changed and modified variously without departing from the gist of the invention.

For example, although in the second embodiment, the case where the paste 5b of the dicing tape 5 is hardened by UV irradiation, the hardening may be done by cooling. In the case where the hardening is done by cooling, it is preferable that prior to the bending (breaking), the dicing tape 5 is cooled to effect hardening of the paste 5b, the semiconductor wafer is bent in this state, the dicing tape is cooled again to effect hardening the paste before the expanding, and the expanding is performed in this state because the dicing tape 5 returns to a normal temperature after the bending.

This invention is suitable to a semiconductor manufacturing technology using a dicing tape.

1. A manufacturing method of a semiconductor device, comprising the steps of:
(a) forming a fractured layer in the interior of a semiconductor wafer by irradiating laser light onto the semiconductor wafer;
(b) mounting the semiconductor wafer on a dicing tape via an adhesive layer;
(c) hardening the adhesive layer of the dicing tape;
(d) dividing the semiconductor wafer starting from the fractured layer by bending the semiconductor wafer; and
(e) expanding chip spacings by stretching the dicing tape from its peripheral part.

2. The manufacturing method of a semiconductor device according to claim 1,
wherein the adhesive layer of the dicing tape is of an ultraviolet curing type.

3. The manufacturing method of a semiconductor device according to claim 1,
wherein after the step (a), the semiconductor wafer is mounted on the dicing tape so that a backside of the semiconductor wafer and the adhesive layer of the dicing tape may contact each other.

4. The manufacturing method of a semiconductor device according to claim 1,
further comprising the step of calculating positions onto which the laser light is to be irradiated by irradiating infrared radiation in the scribe area of the semiconductor wafer.

5. The manufacturing method of a semiconductor device according to claim 1,
wherein an adhesive film is attached to a backside of the semiconductor wafer.

6. The manufacturing method of a semiconductor device according to claim 1,
wherein a wavelength of the laser light is 1064 nm.

7. The manufacturing method of a semiconductor device according to claim 1,
wherein an inspection pattern is formed in a scribe area of the principal plane of the semiconductor wafer.

8. A manufacturing method of a semiconductor device, comprising the steps of:
(a) forming a fractured layer in the interior of a semiconductor wafer by irradiating laser light onto the semiconductor wafer;
(b) mounting the semiconductor wafer on a dicing tape via an adhesive layer;
(c) irradiating ultraviolet radiation on the dicing tape;
(d) dividing the semiconductor wafer at the fractured layer by bending it; and
(e) expanding chip spacings by stretching the dicing tape from its peripheral part.

9. The manufacturing method of a semiconductor device according to claim 8,
wherein the adhesive layer of the dicing tape is of an ultraviolet curing type.

10. The manufacturing method of a semiconductor device according to claim 8,
wherein after the step (a), the semiconductor wafer is mounted on the dicing tape so that a backside of the semiconductor wafer and an adhesive layer of the dicing tape may contact each other.

11. The manufacturing method of a semiconductor device according to claim 8,
wherein in the step (c), the dicing tape is hardened by irradiating the ultraviolet radiation.

12. The manufacturing method of a semiconductor device according to claim 11,
wherein when irradiating the ultraviolet radiation, the radiation is irradiated from the backside side of the semiconductor wafer.

13. The manufacturing method of a semiconductor device according to claim 8,
further comprising the step of calculating positions onto which the laser light is to be irradiated by irradiating infrared radiation on the scribe area of the semiconductor wafer, taking place prior to the step (a).

14. The manufacturing method of a semiconductor device according to claim 8,
wherein an adhesive film is attached on a backside of the semiconductor wafer.

15. A manufacturing method of a semiconductor device, comprising the steps of:
(a) forming a fractured layer in the interior of the semiconductor wafer by irradiating laser light onto the semiconductor wafer;
(b) mounting the semiconductor wafer on a dicing tape via an adhesive layer;
(c) cooling the dicing tape;
(d) dividing the semiconductor wafer at the fractured layer by bending it;
(e) cooling the dicing tape; and
(f) expanding chip spacings by stretching the dicing tape from its peripheral part.

16. The manufacturing method of a semiconductor device according to claim 15,
wherein after the step (a), the semiconductor wafer is mounted on the dicing tape so that a backside of the semiconductor wafer and the adhesive layer of the dicing tape may contact each other.

17. The manufacturing method of a semiconductor device according to claim 15,
wherein in the step (c), the dicing tape is hardened by cooling it as described in the step (e).

18. The manufacturing method of a semiconductor device according to claim 15,
further comprising the step of calculating positions onto which the laser light is to be irradiated by irradiating infrared radiation on a scribe area of the semiconductor wafer, taking place prior to the step (a).

19. The manufacturing method of a semiconductor device according to claim 15,
wherein an adhesive film is attached on a backside of the semiconductor wafer.

20. A manufacturing method of a semiconductor device, comprising the steps of:
(a) preparing a semiconductor wafer having a principal plane and a backside facing the principal plane, an adhesive film being attached to the backside;
(b) forming a fractured layer in the interior of the semiconductor wafer by irradiating laser light onto the semiconductor wafer;
(c) mounting the semiconductor wafer on a dicing tape via the adhesive film;
(d) irradiating ultraviolet radiation on the dicing tape;
(e) dividing the semiconductor wafer at the fractured layer by bending it;
(f) hardening the adhesive film; and
(g) expanding chip spacings by stretching the dicing tape from its peripheral part.

21. The manufacturing method of a semiconductor device according to claim 20,
wherein after the step (a), the semiconductor wafer on the dicing tape is so mounted that the adhesive film of the backside of the semiconductor wafer and an adhesive layer of the dicing tape may contact together.

22. The manufacturing method of a semiconductor device according to claim 20,
further comprising the step of irradiating infrared radiation on a scribe area of the semiconductor wafer to calculate positions onto which the laser light is to be irradiated, taking place prior to the step (a).

23. The manufacturing method of a semiconductor device according to claim 20,
wherein in the step (d), the dicing tape is hardened by irradiating the ultraviolet radiation.

24. A manufacturing method of a semiconductor device, comprising the steps of:
(a) preparing a semiconductor wafer having a principal plane and a backside facing the principal plane;
(b) attaching a tape for grinding on the principal plane of the semiconductor wafer;
(c) measuring a thickness of the semiconductor wafer by irradiating infrared radiation on the semiconductor wafer and detecting its reflected light;
(d) grinding a backside of the semiconductor wafer based on the measurement result of thickness;
(e) calculating points onto which the laser light is to be irradiated by irradiating infrared radiation on a scribe area of the semiconductor wafer;
(f) forming a fractured layer in the interior of the semiconductor wafer by irradiating the laser light onto the semiconductor wafer;
(g) attaching an adhesive film on the backside of the semiconductor wafer;
(h) mounting the semiconductor wafer on a dicing tape via the adhesive film and subsequently peeling the tape for grinding;
(i) irradiating ultraviolet radiation on the dicing tape;
(j) dividing the semiconductor wafer at the fractured layer by bending it;
(k) hardening the adhesive film;
(l) expanding chip spacings by stretching the dicing tape from its peripheral part;
(m) picking up semiconductor chips formed in the step (l); and
(n) mounting the semiconductor chip on a circuit board.

25. The manufacturing method of a semiconductor device according to claim 24,
wherein the adhesive layer of the dicing tape is of an ultraviolet curing type.

26. The manufacturing method of a semiconductor device according to claim 24,
further comprising the steps of:
(o) connecting an electrode of the semiconductor chip and an electrode of the circuit board using conductive wire; and
(p) sealing the semiconductor chip and the wire with a resin, both taking place after the step (m).
